(19) United States
(12) Patent Application Publication
(10) Pub. No.: US 2024/0364304 A1
(43) Pub. Date: Oct. 31, 2024

(54) ACOUSTIC WAVE DEVICE

(71) Applicant: Murata Manufacturing Co., Ltd., Nagaokakyo-shi (JP)

(72) Inventor: Yasunobu HAYASHI, Nagaokakyo-shi (JP)

(21) Appl. No.: 18/766,882

(22) Filed: Jul. 9, 2024

Related U.S. Application Data
(63) Continuation of application No. PCT/JP2023/006761, filed on Feb. 24, 2023.

(30) Foreign Application Priority Data
Mar. 29, 2022 (JP) 2022-053803

(51) Int. Cl. H03H 9/145; H03H 3/08; H03H 9/02; H03H 9/25

(52) U.S. Cl. CPC H03H 9/145; H03H 3/08; H03H 9/02637; H03H 9/02834; H03H 9/25

(57) ABSTRACT

An acoustic wave device includes a piezoelectric substrate and an interdigital transducer electrode on the piezoelectric substrate. The interdigital transducer electrode includes a layer including an electrode material including a base element A and an additive B, where a metal element serving as the base element is denoted by A, and an element serving as the additive is denoted by B. The base element A and the additive B are two types of elements that do not form a compound in a binary phase diagram. The additive B is granularly dispersed in the base element A in the electrode material.

### CROSS REFERENCE TO RELATED APPLICATIONS

This application claims the benefit of priority to Japanese Patent Application No. 2022-053803 filed on Mar. 29, 2022 and is a Continuation Application of PCT Application No. PCT/JP2023/006761 filed on Feb. 24, 2023. The entire contents of each application are hereby incorporated herein by reference.

### BACKGROUND OF THE INVENTION

### 1. Field of the Invention

The present invention relates to acoustic wave devices.

### 2. Description of the Related Art

To date, acoustic wave devices have been widely used for filters of cellular phones and the like. Japanese Unexamined Patent Application Publication No. 2004-153654 discloses a surface acoustic wave element as an example of the acoustic wave device. In the surface acoustic wave element, a comb-shaped electrode portion is disposed on a piezoelectric substrate. An IDT (Interdigital Transducer) electrode is formed from a pair of comb-shaped electrode portions. The comb-shaped electrode portion includes a Ta layer and a CuM alloy layer. The CuM alloy layer is stacked on the Ta layer. An element M is one or more of Ag, Sn, and C. It is preferable that the element M be precipitated at a crystal grain boundary of the CuM alloy grain.

### SUMMARY OF THE INVENTION

However, as described in Japanese Unexamined Patent Application Publication No. 2004-153654, in a state in which the element M is precipitated at a crystal grain boundary of the CuM alloy grain, the resistance of the comb-shaped electrode portion is not sufficiently lowered.

Example embodiments of the present invention provide acoustic wave devices each capable of effectively lowering an electrical resistance of an interdigital transducer electrode.

An acoustic wave device according to an example embodiment of the present invention includes a piezoelectric substrate and an interdigital transducer electrode on the piezoelectric substrate, in which the interdigital transducer electrode includes a layer including an electrode material including a base element A and an additive B, where a metal element serving as the base element is denoted by A, and an element serving as the additive is denoted by B, the base element A and the additive B are two types of elements that do not form a compound in a binary phase diagram, and the additive B is granularly dispersed in the base element A in the electrode material.

According to example embodiments of acoustic wave devices of the present invention, the electrical resistance of the interdigital transducer electrode can be effectively lowered.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view illustrating an acoustic wave device according to a first example embodiment of the present invention.

FIG. 2 is a schematic plan view illustrating the acoustic wave device according to the first example embodiment of the present invention.

FIG. 3 is a binary phase diagram of Cu and Ag.

FIGS. 4A to 4D are schematic elevational cross-sectional views illustrating an example of a method for manufacturing the acoustic wave device according to the first example embodiment of the present invention.

FIG. 5A is a TEM image of an alloy film before heat treatment, and FIG. 5B is a TEM image of an electrode material formed by heat treatment.

FIG. 6 is a TEM-EDX image of an electrode material of an interdigital transducer electrode according to the first example embodiment of the present invention.

FIG. 7 is a diagram illustrating the results of X-ray diffraction of an alloy film before heat treatment and an electrode material formed by heat treatment according to the first example embodiment of the present invention.

FIG. 8 is a diagram illustrating the Hall-Petch relationship and the inverse Hall-Petch relationship.

FIG. 9 is a diagram illustrating input powers at failure in the first example embodiment and a comparative example.

FIG. 10 is a diagram illustrating the relationship between a weight percent concentration of an additive and a ratio of the resistivity with reference to Cu of the electrode material in the first example embodiment and a second comparative example.

### DETAILED DESCRIPTION OF THE EXAMPLE EMBODIMENTS

The present invention will be clarified by describing specific example embodiments according to the present invention with reference to the drawings.

In this regard, each example embodiment described in the present specification is an exemplification, and configurations in different example embodiments can be partly replaced or combined with each other.

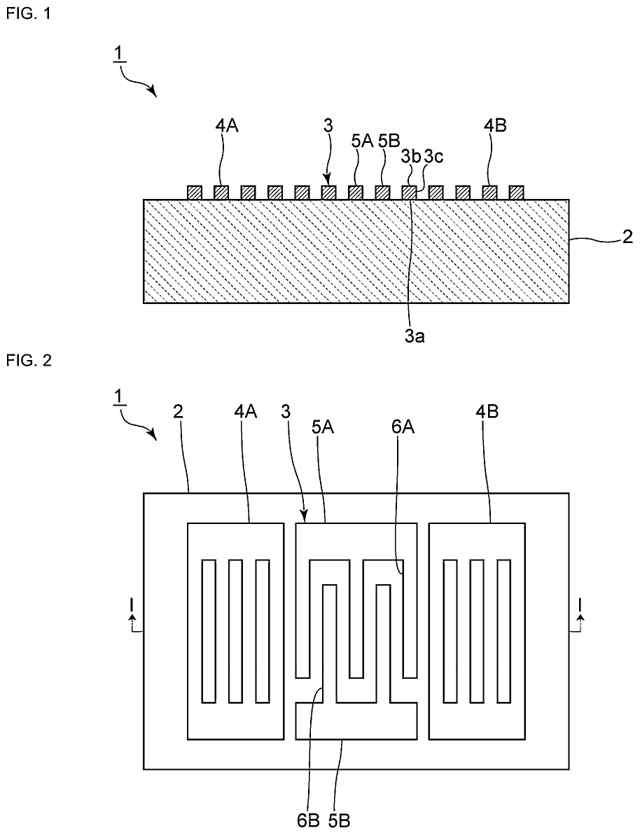

FIG. 1 is a schematic elevational cross-sectional view illustrating an acoustic wave device according to a first example embodiment of the present invention. FIG. 2 is a schematic plan view illustrating the acoustic wave device according to the first example embodiment of the present invention. In this regard, FIG. 1 is a schematic cross-sectional view of the cross section taken along line I-I in FIG. 2.

As illustrated in FIG. 1, an acoustic wave device 1 includes a piezoelectric substrate 2. In the present example embodiment, the piezoelectric substrate 2 is a substrate formed from only a piezoelectric layer. Examples of the material usable for forming the piezoelectric layer include lithium tantalate, lithium niobate, zinc oxide, aluminum nitride, quartz, or PZT (lead zirconate titanate). In this regard, the piezoelectric substrate 2 may be formed from a multilayer substrate including a piezoelectric layer.

An interdigital transducer electrode 3 is disposed on the piezoelectric substrate 2. An acoustic wave is excited by applying alternating-current voltage to the interdigital transducer electrode 3. A pair of reflector 4A and reflector 4B are disposed on both sides of the interdigital transducer electrode 3 in the acoustic wave propagation direction on the piezoelectric substrate 2. Accordingly, the acoustic wave device 1 according to an example embodiment of the present invention is a surface acoustic wave resonator. In this regard, the acoustic wave devices of example embodiments of the present invention are not limited to the acoustic wave resonator and may be, for example, a filter device or a multiplexer including a plurality of acoustic wave resonators.

As illustrated in FIG. 2, the interdigital transducer electrode 3 includes a first busbar 5A, a second busbar 5B, a plurality of first electrode fingers 6A, and a plurality of second electrode fingers 6B. The first busbar 5A and the second busbar 5B are opposite each other. An end of each of the plurality of first electrode fingers 6A is coupled to the first busbar 5A. An end of each of the plurality of second electrode fingers 6B is coupled to the second busbar 5B. The plurality of first electrode fingers 6A are interdigitated with the plurality of second electrode fingers 6B. Hereafter the first electrode finger 6A and the second electrode finger 6B also collectively simply referred to as the electrode finger.

In the present example embodiment, the interdigital transducer electrode 3, the reflector 4A, and the reflector 4B are composed of a single metal layer, for example. However, the interdigital transducer electrode 3, the reflector 4A, and the reflector 4B may be composed of a multilayer body.

The present example embodiment has a feature that the electrode material used for the interdigital transducer electrode 3 has all configurations of 1) to 3) below. 1) A base element A and an additive B are included, where a metal element serving as the base element is denoted by A, and an element serving as the additive is denoted by B. The base element in the present specification is an element a proportion of which is more than about 50 at % in the electrode material, for example. 2) The base element A and the additive B are two types of elements that do not form a compound in a binary phase diagram. 3) In the electrode material, the additive B is granularly dispersed in the base element A. Accordingly, the electrical resistance of the entire electrode material used for the interdigital transducer electrode 3 can be lowered. Therefore, the electrical resistance of the interdigital transducer electrode 3 can be effectively lowered.

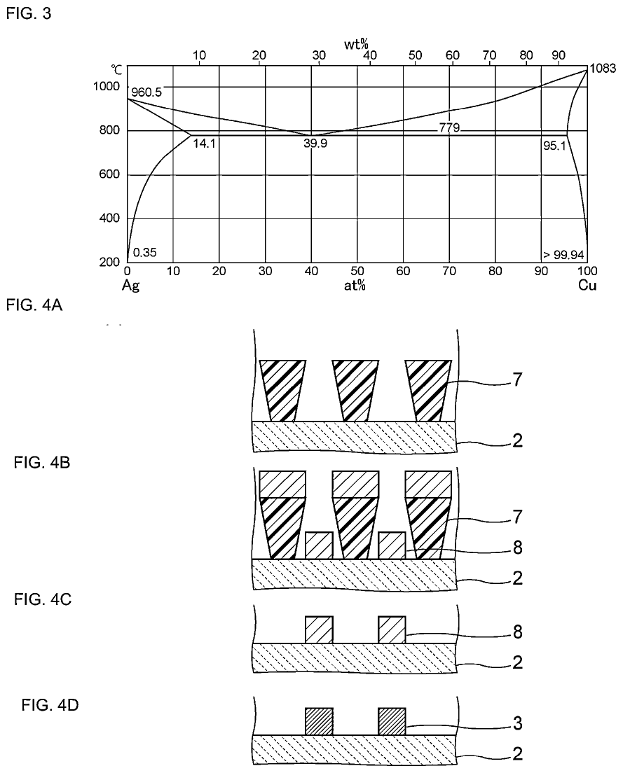

Specifically, in the present example embodiment, the base element A in the electrode material of the interdigital transducer electrode 3 is Cu. The additive B is Ag. The binary phase diagram of the base element Cu and the additive Ag is illustrated in FIG. 3.

FIG. 3 is a binary phase diagram of Cu and Ag.

As clearly illustrated in FIG. 3, Cu and Ag do not form an intermetallic compound. The electrical resistance of an intermetallic compound made of two types of metal elements may be higher than the electrical resistance of each simple metal element. In contrast to this, since an intermetallic compound is not contained in the electrode material of the present example embodiment, the electrical resistance of the interdigital transducer electrode 3 can be more reliably lowered.

On the other hand, for example, when the base element is Al, and the additive is Cu, segregation of an intermetallic compound CuAl₂ occurs. In such an instance, the electrical resistance of the interdigital transducer electrode increases.

An example of a method for manufacturing the acoustic wave device 1 according to the present example embodiment will be described below.

FIGS. 4A to 4D are schematic elevational cross-sectional views illustrating an example of a method for manufacturing the acoustic wave device according to the first example embodiment of the present invention. FIGS. 4A to 4D illustrate a portion corresponding to a pair of electrode fingers and the vicinity thereof.

As illustrated in FIG. 4A, a resist pattern 7 is formed on the piezoelectric substrate 2. Thereafter, as illustrated in FIG. 4B, an alloy film 8 is formed on the piezoelectric substrate 2 and the resist pattern 7. The formation of the alloy film 8 may be performed by, for example, alloy vapor deposition where a Cu—Ag alloy is made into a pellet. In the pellet, Ag may be, for example, about 1 wt %. During the alloy vapor deposition, the ultimate vacuum may be, for example, about 6×10⁻⁴ Pa or less. The acceleration voltage may be, for example, 10 kV. In such an instance, the alloy film 8 in which Ag is, for example, about 19 wt % is obtained.

Subsequently, the resist pattern 7 is peeled off. Consequently, as illustrated in FIG. 4C, the alloy film 8 is patterned. Next, the alloy film 8 is heat-treated. The heat treatment temperature may be set to be, for example, about 250° C. or higher and about 290° C. or lower. The heat treatment time may be set to be, for example, about 2 hours or more and about 10 hours or less. Consequently, the electrode material is formed. The additive Ag is dispersed in the base element Cu by the above-described heat treatment. That is, as illustrated in FIG. 4D, the interdigital transducer electrode 3 made of the electrode material according to the present example embodiment is obtained by the above-described heat treatment.

In the manufacturing method illustrated in FIGS. 4A to 4D, a lift-off method is used. However, the manufacturing method is an example, and the lift-off method is not limited to being used for forming the interdigital transducer electrode 3. For example, after the alloy film is formed on the piezoelectric substrate 2, a resist pattern may be formed on the alloy film, and etching may be performed thereafter. Formation of the alloy film is not limited to alloy vapor deposition, and, for example, binary vapor deposition of the base element A and the additive B may be performed. Alternatively, a sputtering method may be used. It is sufficient that the base element A and the additive B are used as the film-forming material and are simultaneously made into a film.

The state of the additive B in the electrode material of the interdigital transducer electrode 3 can be observed by using TEM (Transmission Electron Microscope). The additive Ag being dispersed in the base element Cu by the above-described heat treatment will be described below.

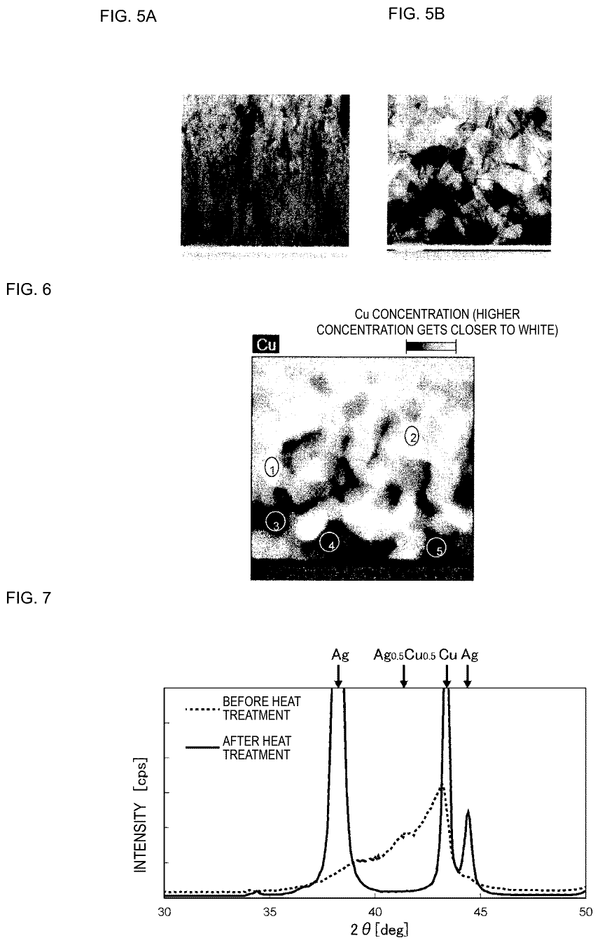

FIG. 5A is a TEM image of the alloy film before heat treatment. FIG. 5B is a TEM image of the electrode material formed by heat treatment. In this regard, a black grain in FIG. 5B is a crystal grain of the additive Ag.

As illustrated in FIG. 5A, in the alloy film before heat treatment, the base element Cu and the additive Ag are in a state of being mixed. As clearly illustrated in FIG. 5B, a crystal grain of the additive Ag is precipitated in the base element Cu after heat treatment.

In the alloy film before heat treatment, the base element Cu and the additive Ag are mixed and stacked. The alloy film is in a supersaturated solid solution state. More specifically, the base element Cu and the additive Ag in a supersaturated state with each other form a solid solution. The reason for this is that Cu and Ag serving as film-forming materials are rapidly cooled when being attached during formation of the alloy film. The resistivity is high in such a “supersaturated solid solution” state.

Thereafter, when heat treatment is performed, the alloy in a supersaturated solid solution state is separated into Cu grains and Ag grains. Therefore, in the obtained electrode material, grains of the additive Ag are dispersed between grains of the base element Cu. Such behavior in which grains of the additive in a supersaturated state are dispersed and precipitated in the base element by heat treatment occurs with respect to only a combination of limited elements such as Cu and Ag.

In this regard, in more detail, the above-described alloy film is separated into Cu grains including Ag as a solute and Ag grains including Cu as a solute by heat treatment. The base element Cu grain in the electrode material includes, for example, the additive Ag serving as a solute at a concentration close to the solid solubility limit. The additive Ag grain contains, for example, the base element Cu at a concentration close to the solid solubility limit. The concentration of the solid solubility limit is a limit of the concentration at which one element can contain another element as a solute. The concentration of the additive in the base element of the electrode material or the concentration of the base element in the additive can be measured by using TEM-EDX (Energy Dispersive X-ray Spectroscopy). In this regard, the concentration in the present specification is a concentration [at %] based on the atomic composition percentage unless other units are described or unless otherwise specified.

FIG. 6 is a TEM-EDX image of the electrode material of the interdigital transducer electrode according to the first example embodiment of the present invention. In this regard, a circular frame line in FIG. 6 indicates a measurement point, and a number indicates a number of the measurement point. In FIG. 6, a higher Cu concentration gets closer to white.

At Measurement point 1, a Cu concentration is about 98.5 at %, and a Ag concentration is about 1.5 at %. At Measurement point 2, a Cu concentration is about 98.5 at %, and a Ag concentration is about 1.5 at %. Accordingly, the Cu grain includes Ag serving as a solute at a concentration of the solid solubility limit or close to the solid solubility limit. At Measurement point 3, a Ag concentration is about 97.5 at %, and a Cu concentration is about 2.5 at %. At Measurement point 4, a Ag concentration is about 97.3 at %, and a Cu concentration is about 2.7 at %. At Measurement point 5, a Ag concentration is about 97.5 at %, and a Cu concentration is about 2.5 at %. Accordingly, the Ag grain includes Cu serving as a solute at a concentration of the solid solubility limit or close to the solid solubility limit.

It is preferable that a temperature range in which a concentration of the additive B capable of being contained, as a solute, in the base element A is about 10 at % or less be present in the binary phase diagram. Consequently, in the electrode material, the concentration of the additive B contained as a solute in the base element A can be reliably set to be about 10 at % or less. Accordingly, the electrical resistance of the interdigital transducer electrode 3 can be more reliably effectively lowered.

In the present example embodiment, as illustrated in FIG. 3, at least in a temperature range of about 700° C. or lower, the concentration of the additive Ag capable of being contained as a solute in the base element Cu is about 10 at % or less. More specifically, the concentration of the solid solubility limit of the additive Ag in the base element Cu decreases with lowering temperature. In such an instance, although not illustrated in FIG. 3, it can be said that the concentration of the additive Ag capable of being contained as a solute in the base element Cu is also about 10 at % or less at normal temperature.

It can be ascertained by, for example, X-ray diffraction that the electrode material obtained by heat treatment contains no supersaturated solid solution.

FIG. 7 is a diagram illustrating the results of X-ray diffraction of the alloy film before heat treatment and the electrode material formed by heat treatment according to the first example embodiment.

As illustrated in FIG. 7, before heat treatment, the intensity is high at the position corresponding to Ag_{0.5}Cu_{0.5} with respect to 20. On the other hand, after heat treatment, peaks of the base element Cu and the additive Ag are present, but a peak of Ag_{0.5}Cu_{0.5} is not present. Therefore, it can be ascertained that the electrode material obtained by heat treatment contains no supersaturated solid solution and that the base element Cu and the additive Ag are separated from each other in the electrode material.

Incidentally, in the electrode material of the interdigital transducer electrode 3 in the acoustic wave device 1, the crystal grain diameter of the base element Cu and the crystal grain diameter of the additive Ag are about 10 nm or more and about 100 nm or less, for example. Consequently, the mechanical strength of the interdigital transducer electrode 3 can be enhanced. This is related to the Hall-Petch relationship and the inverse Hall-Petch relationship.

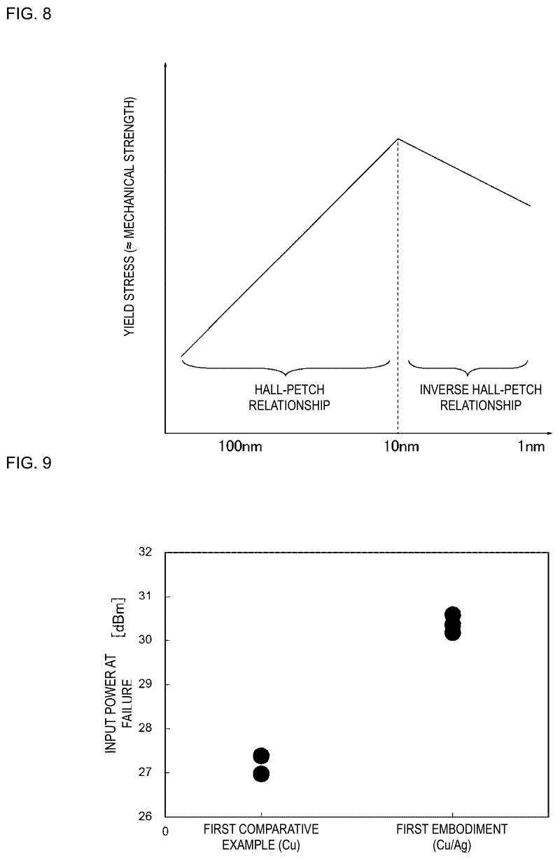

As illustrated in FIG. 8, according to the Hall-Petch relationship, the yield stress of a material increases with decreasing grain diameter in the material. In this regard, it also applies that the mechanical strength of a material increases with decreasing grain diameter in the material. More specifically, when the grain diameter in the material is small, the proportion of grain boundaries in the material increases. The grain boundary has a function of a barrier to dislocation. Dislocation bears plastic deformation. Therefore, the material does not readily undergo plastic deformation with increasing grain boundaries in the material. Consequently, the Hall-Petch relationship applies. On the other hand, when the grain diameter is about 10 nm or less, the yield stress of the material decreases with decreasing grain diameter. This relationship is the inverse Hall-Petch relationship. This is caused by grain boundary sliding.

In the present example embodiment, as illustrated in FIGS. 5A and 5B, the electrode material of the interdigital transducer electrode 3 is formed by grains of the additive B being dispersed and precipitated in the base element A from a supersaturated solid solution state by heat treatment. Consequently, the crystal grain of the base element A and the crystal grain of the additive B are suppressed from becoming coarse. As a result, the crystal grain diameter of the base element A and the crystal grain diameter of the additive B can be more reliably set to be within the range of about 10 nm or more and about 100 nm or less, for example.

On the other hand, when a pure metal is used for the electrode material, it is difficult to prevent the crystal grain from becoming coarse. For example, when a metal film is made of a pure metal and the metal film is heat-treated, a crystal grain of the metal film tends to become coarse.

In this regard, as illustrated in FIG. 1, the layer in which the electrode material is used in the interdigital transducer electrode 3 includes a first surface 3a and a second surface 3b. The first surface 3a and the second surface 3b are opposite each other. Of the first surface 3a and the second surface 3b, the first surface 3a is a piezoelectric-substrate-2-side surface. It is preferable that the concentration of the additive B on the first surface 3a side be higher than the concentration of the additive B on the second surface 3b side. Accordingly, the electric power handling capability of the interdigital transducer electrode 3 can be enhanced.

In the layer in which the electrode material is used, it is preferable that the concentration of the additive B continuously decrease from the first surface 3a side toward the second surface 3b side. Accordingly, the electric power handling capability of the interdigital transducer electrode 3 can be further enhanced.

In the present example embodiment, the example in which the base element A is Cu and the additive B is Ag is described. In this regard, the base element A and the additive B are not limited to the above. The base element A is preferably Cu or Al. When the base element A is Cu, the additive B is preferably an element selected from the group consisting of Ag, Co, Cr, Fe, Ir, Li, Mo, Na, Nb, V, or W. On the other hand, when the base element A is Al, the additive B is preferably an element selected from the group consisting of In, Si, Sn, or Zn. In an instance in which the combination of the base element A and the additive B is any one of the above, the electrical resistance of the interdigital transducer electrode 3 can be effectively lowered as in the present example embodiment.

The resistivity of the simple base element A is preferably about 50 nΩm or less, for example. The resistivity of the simple additive B is about 200 nΩm or less, for example. Accordingly, the electrical resistance of the interdigital transducer electrode 3 can be more reliably lowered.

FIG. 1 schematically illustrates a cross section of each electrode finger in the direction orthogonal to the direction in which each electrode finger extends. The cross-sectional shape of each electrode finger is illustrated as a rectangle. However, the cross-sectional shape of each electrode finger may be for example, a trapezoid. In this regard, in the present example embodiment, since the interdigital transducer electrode 3 is composed of only the layer in which the electrode material according to the present invention is used, the side surface of each electrode finger corresponds to a side surface 3c of the layer in which the electrode material is used. The side surface 3c may extend parallel or substantially parallel to the normal direction of a principal surface of the piezoelectric substrate 2 or may extend slantingly with respect to the normal.

As described above, the interdigital transducer electrode 3 may include a multilayer body. In such an instance, it is sufficient that the interdigital transducer electrode 3 includes the layer in which the electrode material according to the present invention is used.

A dielectric film may be disposed on the piezoelectric substrate 2 so as to cover the interdigital transducer electrode 3. In such an instance, the interdigital transducer electrode 3 is not readily damaged. Regarding the dielectric film, for example, silicon oxide, silicon nitride, or silicon oxynitride may be used. When silicon oxide is used for the dielectric film, frequency temperature characteristics of the acoustic wave device 1 can be improved.

In the first example embodiment, the electric power handling capability of the interdigital transducer electrode 3 can be enhanced, and the electrical resistance of the interdigital transducer electrode 3 can be lowered. This is specifically described below by comparing the first example embodiment with a first comparative example and a second comparative example.

The first comparative example differs from the first example embodiment in that the interdigital transducer electrode is made of Cu. That is, in the first comparative example, the additive is not contained in the electrode material of the interdigital transducer electrode. In this regard, in the first example embodiment, the base element is Cu and the additive is Ag in the electrode material.

Regarding the first example embodiment and the first comparative example, the electric power handling capability was compared. Specifically, a plurality of acoustic wave devices having the configuration according to the first example embodiment and a plurality of acoustic wave devices according to the first comparative example were prepared, and an electric power was applied to each acoustic wave device. A larger input electric power when the acoustic wave device failed due to the interdigital transducer electrode being damaged corresponds to higher electric power handling capability of the interdigital transducer electrode.

FIG. 9 is a diagram illustrating input powers at failure in the first example embodiment and the comparative example.

As illustrated in FIG. 9, in the first example embodiment, the input power at failure is larger than that in the first comparative example. Accordingly, regarding the first example embodiment, the electric power handling capability of the interdigital transducer electrode can be enhanced.

Further, regarding the first example embodiment and the second comparative example, the electrical resistance of the electrode material of the interdigital transducer electrode was compared. In this regard, in the second comparative example, the base element is Cu and the additive is Sn in the electrode material. Regarding the electrode material in each of the first example embodiment and the second comparative example, the resistivity of the electrode material was measured every time the weight percent concentration [wt %] of the additive was changed. Subsequently, regarding each electrode material, the ratio of the resistivity with reference to the resistivity of Cu was calculated.

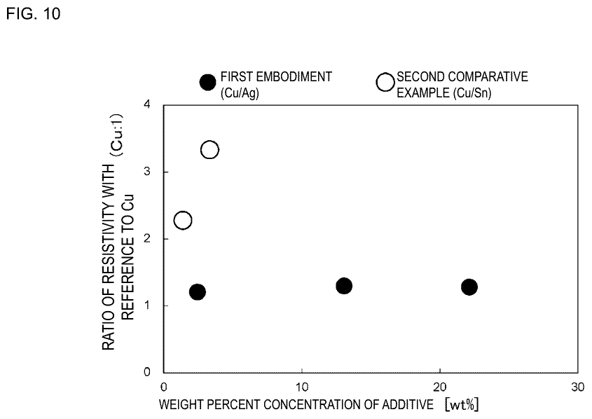

FIG. 10 is a diagram illustrating the relationship between the weight percent concentration of the additive and the ratio of the resistivity with reference to Cu regarding the electrode material in the first example embodiment and the second comparative example. The resistivity of the electrode material increases with increasing ratio of the resistivity with reference to Cu regarding the electrode material.

As illustrated in FIG. 10, regarding the second comparative example, the resistivity of the electrode material increases with increasing weight percent concentration of the additive. On the other hand, in the first example embodiment, the resistivity of the electrode material is almost not changed even when the weight percent concentration of the additive increases. Further, the resistivity of the electrode material in the first example embodiment is lower than the resistivity of the electrode material in the second comparative example. Therefore, in the first example embodiment, the electrical resistance of the interdigital transducer electrode can be lowered.

In the second comparative example, Cu serving as the base element and Sn serving as the additive form an intermetallic compound. Then, in the electrode material in the second comparative example, the intermetallic compound increases with increasing weight percent concentration of the additive. Consequently, the resistivity of the electrode material is high.

On the other hand, in the first example embodiment, Cu serving as the base element and Ag serving as the additive do not form an intermetallic compound. Consequently, the resistivity of the electrode material does not depend on the weight percent concentration of the additive, and the resistivity of the electrode material is low. As described above, in the first example embodiment, the electric power handling capability of the interdigital transducer electrode can be enhanced, and the electrical resistance of the interdigital transducer electrode can be lowered.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an interdigital transducer electrode on the piezoelectric substrate; wherein
the interdigital transducer electrode includes a layer including an electrode material including a base element A and an additive B, where a metal element serving as the base element is denoted by A, and an element serving as the additive is denoted by B;
the base element A and the additive B are two types of elements that do not form a compound in a binary phase diagram; and
the additive B is granularly dispersed in the base element A in the electrode material.

2. The acoustic wave device according to claim 1, wherein a crystal grain diameter of the base element A and a crystal grain diameter of the additive B are about 10 nm or more and about 100 nm or less in the electrode material.

3. The acoustic wave device according to claim 1, wherein
the base element A is Cu; and
the additive B is at least one of Ag, Co, Cr, Fe, Ir, Li, Mo, Na, Nb, V, or W.

4. The acoustic wave device according to claim 1, wherein
the base element A is Al; and
the additive B is at least one of In, Si, Sn, or Zn.

5. The acoustic wave device according to claim 1, wherein a resistivity of a simple substance of the base element A is about 50 nΩm or less.

6. The acoustic wave device according to claim 1, wherein a resistivity of a simple substance of the additive B is about 200 nΩm or less.

7. The acoustic wave device according to claim 1, wherein a temperature range in which a concentration [at %] of the additive B capable of being contained, as a solute, in the base element A is about 10 at % or less is present in the binary phase diagram.

8. The acoustic wave device according to a claim 1, wherein
the layer in which the electrode material is included, in the interdigital transducer electrode, includes a first surface and a second surface opposite each other, the first surface being a piezoelectric-substrate-side surface of the first surface and the second surface; and
a concentration [at %] of the additive B on the first surface side of the layer in which the electrode material is used is higher than a concentration [at %] of the additive B on the second surface side.

9. The acoustic wave device according to claim 8, wherein, in the layer in which the electrode material is included, the concentration [at %] of the additive B continuously decreases from the first surface side toward the second surface side.

10. The acoustic wave device according to claim 1, wherein the piezoelectric substrate includes only a piezoelectric layer.

11. The acoustic wave device according to claim 1, wherein the piezoelectric substrate is a multilayer substrate including a piezoelectric layer.

12. The acoustic wave device according to claim 1, further comprising reflectors on both sides of the interdigital transducer electrode.

13. The acoustic wave device according to claim 1, wherein the acoustic wave device is a surface acoustic wave resonator.

14. The acoustic wave device according to claim 12, wherein the interdigital transducer electrode and the reflectors are each defined by a single metal layer.

15. The acoustic wave device according to claim 12, wherein the interdigital transducer electrode and the reflectors are each defined by a multilayer body.

16. The acoustic wave device according to claim 1, further comprising a dielectric film covering the interdigital transducer electrode.

17. The acoustic wave device according to claim 16, wherein the dielectric film is silicon oxide, silicon nitride, or silicon oxynitride.
